(19) United States
(12) Patent Application Publication
(10) Pub. No.: US 2016/0091742 A1
(43) Pub. Date: Mar. 31, 2016

(54) DISPLAY PANEL

(71) Applicant: InnoLux Corporation, Jhu-Nan (TW)

(72) Inventors: Jung-Fang CHANG, Jhu-Nan (TW); Kuan-Feng LEE, Jhu-Nan (TW); I-Ho SHEN, Jhu-Nan (TW)

(21) Appl. No.: 14/868,096

(22) Filed: Sep. 28, 2015

(30) Foreign Application Priority Data
Sep. 30, 2014 (TW) 103134076

(51) Int. Cl. G02F 1/1339; H01L 29/786; H01L 27/12

(52) U.S. Cl. CPC G02F 1/1339; H01L 27/1225; H01L 29/7869

(57) ABSTRACT

A display panel comprises a first substrate, a second substrate and an organic planarization layer. The first substrate has an active area and a non-active area disposed adjacent to the active area. The second substrate is disposed opposite the first substrate. The organic planarization layer is disposed on the first substrate facing the second substrate and includes at least a first through portion which is disposed in the non-active area and exposes a film layer under the organic planarization layer.

### CROSS REFERENCE TO RELATED APPLICATIONS

This Non-provisional application claims priority under 35 U.S.C. §119(a) on Patent Application No(s). 103134076 filed in Taiwan, Republic of China on Sep. 30, 2014, the entire contents of which are hereby incorporated by reference.

### BACKGROUND OF THE INVENTION

1. Field of Invention

This invention relates to a display panel and, in particular, to a display panel having higher reliability.

2. Related Art

With the progress of technologies, flat display panels have been widely applied to various kinds of fields. Besides, flat display devices, having advantages such as compact structure, low power consumption, less weight and less radiation, gradually take the place of cathode ray tube (CRT) display devices, and are widely applied to various electronic products, such as mobile phones, portable multimedia devices, notebooks, LCD TVs and LCD screens.

By taking a conventional liquid crystal display (LCD) panel as an example, it includes a thin film transistor (TFT) substrate and a color filter substrate which are disposed oppositely. The TFT substrate includes a plurality of TFTs and a plurality of pixel electrodes which are both disposed on a substrate. In the manufacturing process, a via needs to be formed on the drain of the TFT by etching, and a transparent conductive layer is disposed on the inner wall of the via to electrically connect the drain of the TFT and the pixel electrode. Besides, the gate of the TFT is electrically connected with a scan line and the source of the TFT is electrically connected with a data line. When the scan line inputs a scan signal to the gate of the TFT, the TFT is controlled so that the data voltage of the data line can be inputted to the pixel electrode through the source and the drain, and thereby the orientation of the liquid crystal can be controlled for the image display.

Due to the raised market competition, the requirements about the size of the display panel and the color saturation of the display are rapidly increased as well as the demands for the performance and stability of the TFT. Accordingly, the metal oxide-based (MOSs) TFT can be manufactured under the room temperature and possess well current output characteristic, lower leakage current and better electron mobility that is ten times higher than the amorphous silicon TFT (a-Si TFT), so as to reduce the power consumption of the display panel and raise the operation frequency of the display panel. Therefore, the metal oxide-based TFT has become the mainstream driving element in the display panel.

However, although the metal oxide-based TFT has better electrical property, it is easily affected by the moisture and oxygen and thus will worsen the reliability of the display panel. Besides, the material of the organic planarization layer, such as polyfluoroalkoxy (PFA), introduced into the high definition product for increasing the aperture ratio of the display panel has weaker ability to block the moisture than the inorganic material, so that it may absorb the moisture in the manufacturing process to affect the reliability of other elements and TFTs disposed within the display area.

Therefore, it is an important subject to provide a display panel which can have stronger ability to block the moisture so as to enhance the reliability of the product.

### SUMMARY OF THE INVENTION

In view of the foregoing subject, an objective of this invention is to provide a display panel which can have stronger ability to block the moisture so as to enhance the reliability of the product.

To achieve the above objective, a display panel according to the invention comprises a first substrate, a second substrate and an organic planarization layer. The first substrate has an active area and a non-active area disposed adjacent to the active area. The second substrate is disposed opposite the first substrate. The organic planarization layer is disposed on the first substrate facing the second substrate and includes at least a first through portion which is disposed in the non-active area and exposes a film layer under the organic planarization layer.

In one embodiment, the display panel further comprises a blocking layer covering the first through portion.

In one embodiment, the material of the blocking layer is Al2O3, AlNO or AlON.

In one embodiment, the first through portion includes a bottom portion and a width of the bottom portion is between 5 μm and 2000 μm.

In one embodiment, the width of the bottom portion is further between 5 μm and 200 μm.

In one embodiment, the display panel further comprises a sealant connecting the first substrate and the second substrate. The first through portion is disposed between the sealant and the active area.

In one embodiment, the display panel further comprises a sealant connecting the first substrate and the second substrate. The first through portion is disposed in the sealant.

In one embodiment, the number of the first through portion is more than 1.

In one embodiment, the organic planarization layer further includes at least a second through portion which is disposed in the sealant and exposes the film layer under the organic planarization layer, and the blocking layer covers the second through portion.

In one embodiment, the display panel further comprises an electronic element disposed on the first substrate and in the non-active area. The first through portion is disposed between the electronic element and the active area.

In one embodiment, the display panel further comprises a thin film transistor disposed between the first substrate and the organic planarization layer and including a channel layer whose material is oxide semiconductor.

As mentioned above, in the display panel of this invention, the organic planarization layer is disposed on the first substrate facing the second substrate and includes at least a first through portion, and the first through portion is disposed in the non-active area and exposes a film layer under the organic planarization layer. Thereby, when the external moisture permeates the display panel from outside, the disposition of the first through portion can block the permeation path of the moisture in the organic planarization layer, so that the TFT or other elements within the active area won't be affected by the moisture. Therefore, the display panel can have stronger ability to block the moisture, so as to enhance the reliability of the product.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing the relation between the water absorption rate of an organic material and time;

FIG. 2A is a schematic top view of a display panel of an embodiment of the invention;

FIG. 2B is a schematic sectional diagram taken along the line A-A in FIG. 2A;

FIGS. 3A to 3D are schematic diagrams of the display panels of different embodiments of the invention; and

FIG. 4 is a schematic diagram of a display device of an embodiment of the invention.

### DETAILED DESCRIPTION OF THE INVENTION

The present invention will be apparent from the following detailed description, which proceeds with reference to the accompanying drawings, wherein the same references relate to the same elements.

In order to reduce the power consumption of the display panel, raise the operation frequency and increase the aperture ratio, the metal oxide-based TFT and organic material of the planarization layer are introduced into the manufacturing process of the display panel. However, because the metal oxide-based TFT is easily affected by the moisture and oxygen and the ability of the organic material to absorb the moisture is stronger than the inorganic material, the characteristic of the TFT will be easily shifted and the reliability of the display panel will be thus lowered down.

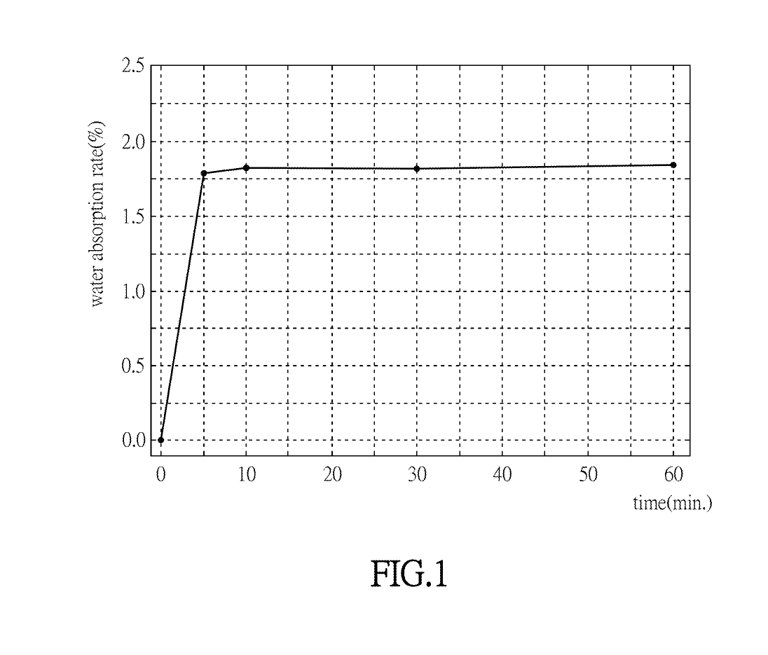

FIG. 1 is a schematic diagram showing the relation between the water absorption rate of an organic material and time. As shown in FIG. 1, after about five minutes, the water absorption rate of the organic material rises to about 1.8%. Accordingly, a display panel of an embodiment of the invention is provided to reduce the water absorption rate so as to enhance the reliability of the display panel.

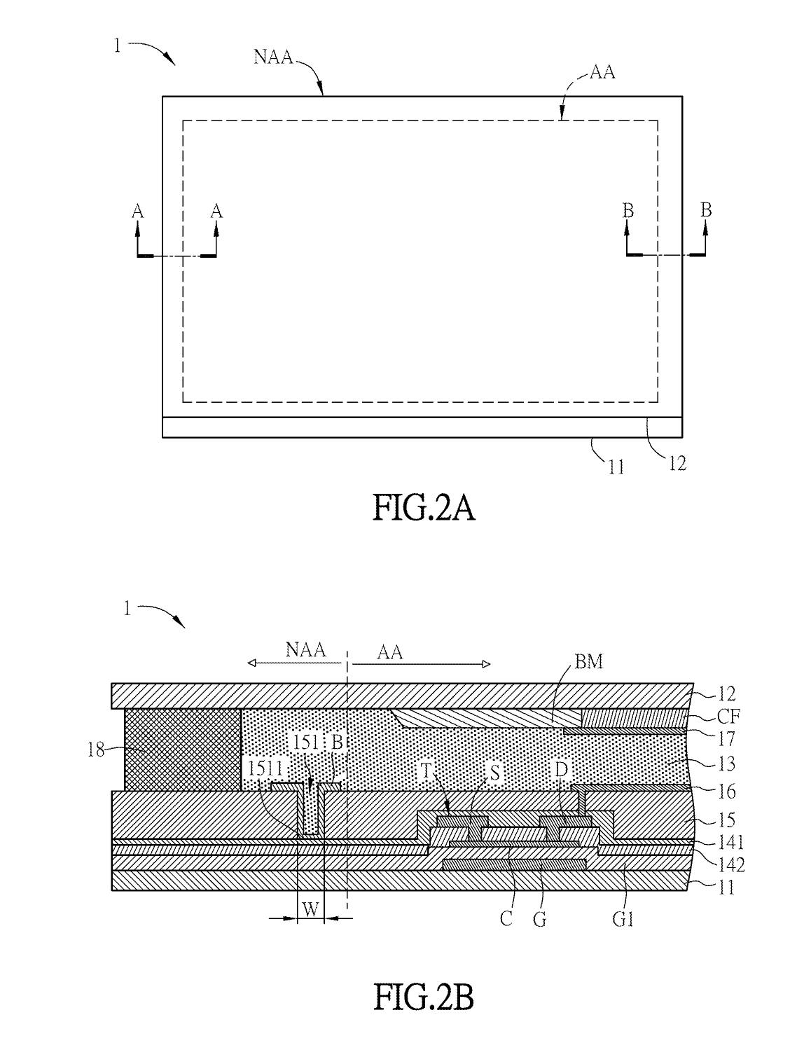

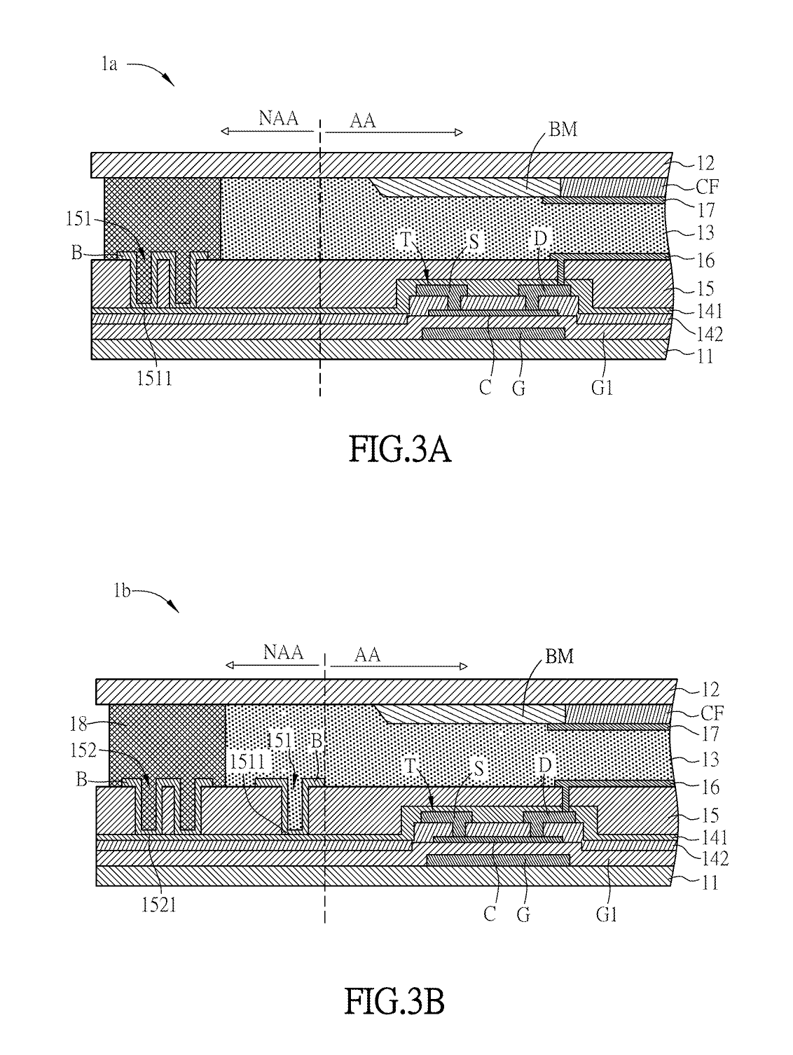

FIG. 2A is a schematic top view of a display panel 1 of an embodiment of the invention, and FIG. 2B is a schematic sectional diagram taken along the line A-A in FIG. 2A. As shown in FIGS. 2A and 2B, the display panel 1 can be an LCD panel or an organic light emitting diode (OLED) display panel, and herein an LCD panel is illustrated as an example.

As shown in FIG. 2B, the display panel 1 includes a first substrate 11, a second substrate 12 and a display medium layer 13. The first substrate 11 has an active area AA and a non-active area NAA disposed adjacent to the active area AA. The active area AA is the area of the first substrate 11 which is pervious to the light and thereby displays images. The non-active area NAA is the area which is impervious to the light. In this embodiment, the non-active area NAA is disposed around the active area AA for example.

The first substrate 11 and the second substrate 12 are disposed oppositely, and the display medium layer 13 is disposed between the first substrate 11 and the second substrate 12. Each of the first substrate 11 and the second substrate 12 is made by transparent material, and can be a glass substrate, a quartz substrate or a plastic substrate for example. The display medium layer 13 of this embodiment is a liquid crystal (LC) layer including a plurality of LC molecules (not shown). In another embodiment where the display panel 1 is an OLED display panel, the display medium layer 13 can be an organic light emitting layer, and meanwhile the second substrate 12 can be a cover plate to protect the organic light emitting layer from the pollution of the external moisture or objects.

The display panel 1 of this embodiment can further include a TFT T, an insulating layer 141, an etch stop layer 142, an organic planarization layer 15, a pixel electrode layer 16, a common electrode layer 17 and a sealant 18. Besides, the display panel 1 can further include a black matrix layer BM and a color filter layer CF.

The TFT T is disposed between the first substrate 11 and the organic planarization layer 15. The TFT T of this embodiment includes a gate G, a gate dielectric layer G1, a channel layer C, a source S and a drain D. The gate G is disposed on the first substrate 11 and can be a single-layer or multi-layer structure formed by metal (e.g. aluminum, copper, silver, molybdenum, or titanium) or alloy. A part of the wires, such as scan lines (not shown), for transmitting driving signals can be the same layer as the gate G and formed in the same process as the gate G, and they can be electrically connected to each other. The gate dielectric layer G1 is disposed on and covers the gate G and can be a multi-layer structure formed by an organic material (such as organic silicon/oxide compound), an inorganic material (such as silicon nitride, silicon oxide, silicon oxynitride, silicon carbide, aluminum oxide, hafnium oxide, solution silicon oxide or silicon nitride), or their any combination. The gate dielectric layer G1 needs to completely cover the gate G and can partially or totally cover the first substrate 11.

The channel layer C corresponds to the position of the gate G to be disposed on the gate dielectric layer G1. In an embodiment, the channel layer C can include an oxide semiconductor for example. The said oxide semiconductor includes an oxide and the oxide includes one of indium, gallium, zinc and tin. For example, the oxide semiconductor is indium gallium zinc oxide (IGZO).

The etch stop layer 142 is disposed on the channel layer C. The source S and the drain D are disposed on the channel layer C and the etch stop layer 142. One end of the source S and one end of the drain D contact the channel layer C through openings of the etch stop layer 142, respectively. Herein for example, the etch stop layer 142 partially covers the channel layer C and the source S and the drain D contact the channel layer C through the openings of the etch stop layer 142. When the channel layer C of the TFT T is not turned on, the source S and the drain D are electrically separated from each other. A part of the wires, such as data lines (not shown), for transmitting driving signals can be the same layer as the source S and drain D and formed in the same process as the source S and drain D. The source S and the drain D can be a single-layer or multi-layer structure formed by metal (e.g. aluminum, copper, silver, molybdenum, or titanium) or alloy. The etch stop layer 142 can be a single-layer or multi-layer structure formed by an organic material (such as organic silicon/oxide compound), an inorganic material (such as silicon nitride, silicon oxide, silicon oxynitride, silicon carbide, aluminum oxide, hafnium oxide), or their any combination.

To be noted, the source S and drain D of the TFT T of this embodiment are disposed on the etch stop layer 142, and one end of the source S and one end of the drain D can contact the channel layer C through openings of the etch stop layer 142, respectively. However, in another embodiment, the source S and drain D of the TFT T can be directly disposed on the channel layer C while the etch stop layer 142 is omitted.

The insulating layer 141 is disposed on the side of the first substrate 11 facing the second substrate 12. Herein for example, the insulating layer 141 is disposed on the source S and the drain D and covers the source S and a part of the drain D. The insulating layer 141 is disposed on the drain D and has a via. The material of the insulating layer 141 can include SiOx or SiNx, but this invention is not limited thereto.

The organic planarization layer 15 is disposed on the first substrate 11 facing the second substrate 12 and covers the insulating layer 141. The material of the organic planarization layer 15 can include PFA for example. The pixel electrode layer 16 is disposed on the organic planarization layer 15 and electrically connected with the drain D of the TFT T through the via of the organic planarization layer 15 and the via of the insulating layer 141. The material of the pixel electrode layer 16 can be, for example, ITO, IZO, AZO, CTO, SnO2, ZnO or other transparent conducting materials.

The black matrix layer BM is disposed on the first substrate 11 or the second substrate 12 and corresponding to the TFT T. The color filter layer CF is disposed on the side of the first substrate 11 facing the second substrate 12 or on the second substrate 12 and disposed corresponding to the pixel electrode layer 16. The color filter layer CF includes a plurality of color filter portions, and the black matrix layer BM is disposed between the color filter portions. The black matrix layer BM and the color filter layer CF of this embodiment are disposed on the second substrate 12. However, in another embodiment, the black matrix layer BM or the color filter layer CF can be disposed on the first substrate 11 for making a BOA (BM on array) substrate or a COA (color filter on array) substrate. To be noted, the above-mentioned structures are just for example but not for limiting the scope of the invention.

The common electrode layer 17 is disposed on the second substrate 12. Herein for example, the common electrode layer 17 is disposed on the color filter layer CF and corresponding to the pixel electrode layer 16. Besides, the display panel 1 can further include a protection layer (such as an over-coating, not shown), which can cover the black matrix layer BM and the color filter layer CF. The protection layer can include photoresist material, resin material or inorganic material (e.g. SiOx/SiNx) and can protect the black matrix layer BM and the color filter layer CF from being damaged during the subsequent processes.

The sealant 18 is disposed between the first substrate 11 and the second substrate 12 and connects the first substrate 11 and the second substrate 12. The sealant 18 of this embodiment is disposed within the non-active area NAA. The sealant 18 can be formed on the periphery of the first substrate 11 by coating under the atmosphere for example, so that the LC molecules can be filled into the room bounded by the sealant 18 for making an LCD panel. However, this invention is not limited thereto. Moreover, the LC molecules can be filled into the room bounded by the sealant 18 by one drop filling (ODF) process for example, but this invention is not limited thereto.

When the scan lines of the display panel 1 receive a scan signal sequentially, the TFTs T corresponding to the scan lines S can be sequentially enabled. Then, the data signals can be transmitted to the corresponding pixel electrode layers 16 through the data lines and the display panel 1 can display images accordingly.

As shown in FIG. 2B, the organic planarization layer 15 includes at least a first through portion 151, and the first through portion 151 is disposed within the non-active area NAA and exposes the film layer that is under the organic planarization layer 15. In this embodiment, the first through portion 151 exposes the insulating layer 141. The first through portion 151 can be, for example but is not limited to, a through hole or a trench disposed around the non-active area NAA. In an embodiment, the organic planarization layer 15 with the first through portion 151 can be defined and formed by photolithography, so that the layer thereunder will be exposed to the top view of the first through portion 151. Herein for example, the display panel 1 includes a single first through portion 151 disposed between the sealant 18 and the active area AA. However, in another embodiment, there can be a plurality of first through portions 151. The first through portion 151 of this embodiment includes a bottom portion 1511 (the insulating layer 141 can be viewed by the top view of the bottom portion 1511), and the width W of the bottom portion 1511 can be between 5 μm and 2000 μm (5 μm ≦W ≦2000 μm). Favorably, the width W of the bottom portion 1511 can be between 5 μm and 200 μm (5 μm ≦W ≦200 μm).

Furthermore, the display panel 1 of this embodiment can further include a blocking layer B covering the first through portion 151. Herein for example, the blocking layer B covers the sidewall and bottom portion 1511 of the first through portion 151 and also covers a part of the organic planarization layer 15. The blocking layer B can be a single-layer or multi-layer structure formed by Al2O3, AlNO or AlON, and herein for example, is a single-layer structure formed by Al2O3. The blocking layer B can be formed by using a hard mask to form an inorganic coating layer along the first through portion 151 or by photolithography, but the above methods are not meant to be construed in a limiting sense.

In this embodiment, a portion of the organic planarization layer 15 within the non-active area NAA is emptied out to form at least a first through portion 151, and the blocking layer B is used to cover the first through portion 151. Therefore, when the external moisture permeates the display panel 1 from outside, the disposition of the first through portion 151 (with the blocking layer B) can block the permeation path of the moisture in the organic planarization layer 15, so that the moisture won't affect the TFT T or other elements within the active area AA. Therefore, the display panel 1 can have stronger ability to block the moisture, so as to enhance the reliability of the product.

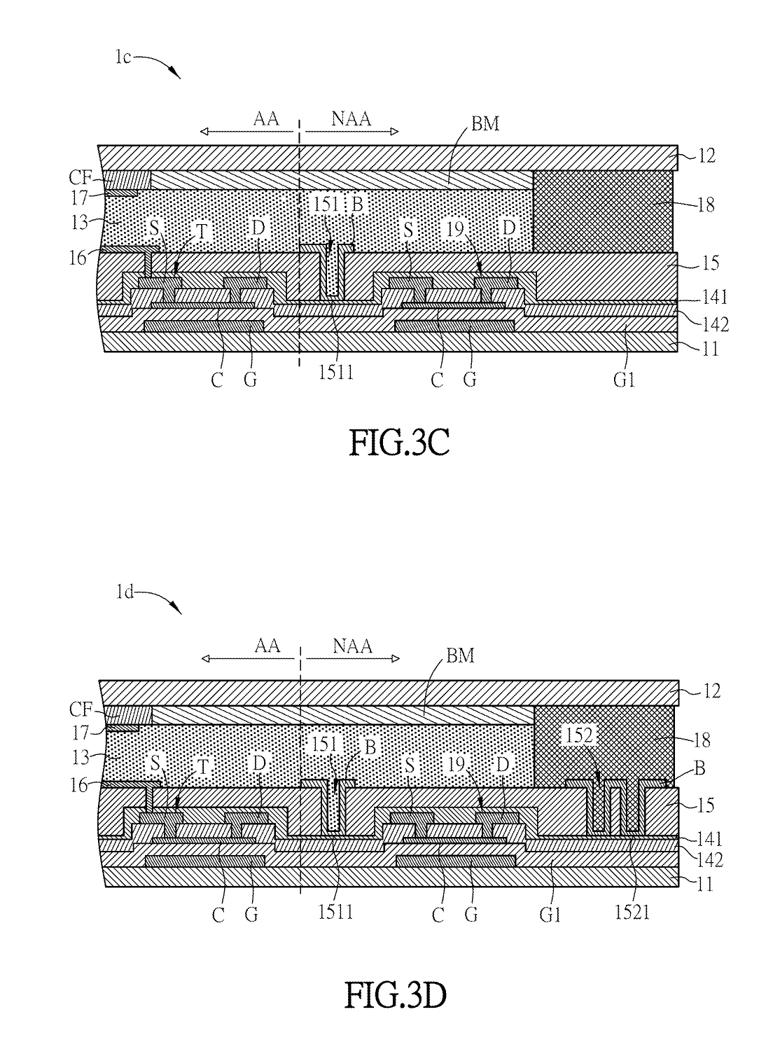

FIGS. 3A to 3D are schematic diagrams of the display panels 1a-1d of different embodiments of the invention.

As shown in FIG. 3A, the main difference between the display panel la and the display panel 1 in FIG. 2B is that the display panel 1a includes two first through portions 151 disposed in the sealant 18 and the blocking layer B still covers the first through portions 151. Of course, in different embodiments, the quantity of the first through portions 151 disposed in the sealant can be varied (such as 3, 4, . . . ). In addition to blocking the permeation path of the moisture in the organic planarization layer 15, the first through portions 151 disposed in the sealant 18 also can increase the contact area between the sealant 18 and the first substrate 11, so as to enhance the adhesion between the sealant 18 and the first substrate 11 and thus increase the reliability of the display panel 1a. Moreover, since the blocking layer B is an inorganic film layer (such as a Al2O3 coating layer) and covers the first through portion 151, this embodiment not only can enhance the connection strength between the first substrate 11 and the second substrate 12, but also can prevent the external moisture and oxygen from permeating the active area AA.

As shown in FIG. 3B, the main difference between the display panel 1b and the display panel 1 in FIG. 2B is that the organic planarization layer 15 of the display panel 1b not only includes a single first through portion 151 disposed between the sealant 18 and the active area AA, but also includes at least a second through portion 152. The second through portion 152 is disposed in the sealant 18 and exposes the film layer under the organic planarization layer 15. Herein, this embodiment includes two second through portions 152 which permeate the organic planarization layer 15 to expose the insulating layer 141, and the blocking layer B is disposed on the second through portions 152.

The technical features of other elements of the display panels 1a, 1b can be comprehended by referring to the display panel 1, and therefore the related illustration is omitted here for conciseness.

FIG. 3C is a schematic sectional diagram of the display panel taken along the line B-B in FIG. 2A. As shown in FIG. 3C, herein the sectional position of the line B-B can be the region of the first substrate 11 where the gate driver circuit is directly formed, i.e. GOP (gate on panel), so that FIG. 3C is the schematic sectional diagram of the region where the gate driver circuit is disposed.

The main difference from the display panel 1 of FIG. 2B is that the display panel 1c of FIG. 3C can further include an electronic element 19. The electronic element 19 is disposed on the first substrate 11 and in the non-active area NAA, and the first through portion 151 is disposed between the electronic element 19 and the active area AA. Herein for example, the electronic element 19 is disposed adjacent to the first through portion 151 and within the non-active area NAA. The electronic element 19 can be a driving element for example, and can be a TFT which can have the structure of the above-mentioned TFT T, so the related illustration is omitted here for conciseness. However, in another embodiment, the electronic element 19 can be not a TFT but another type of element, such as diode, trace or wire. The said trace or wire can be used in the connection between the elements or in the anti-electrostatic discharge. Moreover, in another embodiment, the trace or wire may penetrate the film layer under the first through portion 151.

The technical features of other elements of the display panels 1c can be comprehended by referring to the display panel 1, and therefore the related illustration is omitted here for conciseness.

As shown in FIG. 3D, the main difference from the display panel 1c of FIG. 3C is that the display panel 1d includes two second through portions 152, in addition to the first through portion 151, and the second through portions 152 are disposed in the sealant 18 and the blocking layer B covers the second through portions 152. Accordingly, the first through portion 151, the second through portions 152 and the blocking layer B can block the permeation path of the moisture in the organic planarization layer 15, and besides, the second through portions 152 disposed in the sealant 18 can increase the contact area between the sealant 18 and the first substrate 11, so as to enhance the adhesion between the sealant 18 and the first substrate 11 and thus increase the reliability of the display panel 1d.

The technical features of other elements of the display panels 1d can be comprehended by referring to the display panel 1c, and therefore the related illustration is omitted here for conciseness.

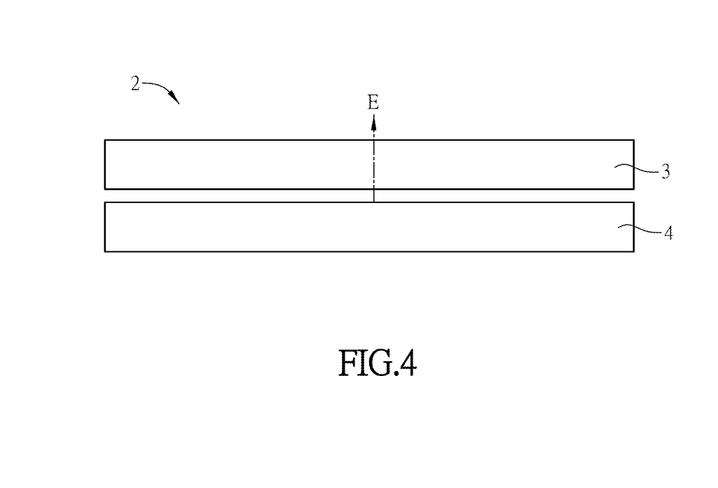

FIG. 4 is a schematic diagram of a display device 2 of an embodiment of the invention.

As shown in FIG. 4, the display device 2 includes a display panel 3 and a backlight module 4 disposed opposite the display panel 3. The display device 2 is an LCD device, and the display panel 3 can include any of the above-mentioned display panels 1, 1a˜1d or their variation, and therefore the related illustration is omitted here for conciseness. When the backlight module 4 emits the light E passing through the display panel 3, the pixels of the display panel 3 can display colors to form images accordingly.

Summarily, in the display panel of this invention, the organic planarization layer is disposed on the first substrate facing the second substrate and includes at least a first through portion, and the first through portion is disposed in the non-active area and exposes a film layer under the organic planarization layer. Thereby, when the external moisture permeates the display panel from outside, the disposition of the first through portion can block the permeation path of the moisture in the organic planarization layer, so that the TFT or other elements within the active area won't be affected by the moisture. Therefore, the display panel can have stronger ability to block the moisture, so as to enhance the reliability of the product.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display panel, comprising:
a first substrate having an active area and a non-active area disposed adjacent to the active area;
a second substrate disposed opposite the first substrate; and
an organic planarization layer disposed on the first substrate facing the second substrate and including at least a first through portion which is disposed in the non-active area and exposes a film layer under the organic planarization layer.

2. The display panel as recited in claim 1, further comprising:
a blocking layer covering the first through portion.

3. The display panel as recited in claim 2, wherein the material of the blocking layer is Al2O3, AlNO or AlON.

4. The display panel as recited in claim 1, wherein the first through portion includes a bottom portion and a width of the bottom portion is between 5 μm and 2000 μm.

5. The display panel as recited in claim 2, further comprising:
a sealant connecting the first substrate and the second substrate, wherein the first through portion is disposed between the sealant and the active area.

6. The display panel as recited in claim 1, further comprising:
a sealant connecting the first substrate and the second substrate, wherein the first through portion is disposed in the sealant.

7. The display panel as recited in claim 6, wherein the number of the first through portion is more than 1.

8. The display panel as recited in claim 5, wherein the organic planarization layer further includes at least a second through portion which is disposed in the sealant and exposes the film layer under the organic planarization layer, and the blocking layer covers the second through portion.

9. The display panel as recited in claim 5, further comprising:
an electronic element disposed on the first substrate and in the non-active area, wherein the first through portion is disposed between the electronic element and the active area.

10. The display panel as recited in claim 1, further comprising:
a thin film transistor disposed between the first substrate and the organic planarization layer and including a channel layer whose material is oxide semiconductor.
